(19) United States
(12) Patent Application Publication
(10) Pub. No.: US 2007/0102727 A1
(43) Pub. Date: May 10, 2007

(54) Field-effect transistor

(75) Inventor: John Kevin Twynam, Yamatokooriyama-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha, Osaka-shi (JP)

(21) Appl. No.: 11/590,791

(22) Filed: Nov. 1, 2006

(30) Foreign Application Priority Data
Nov. 2, 2005 (JP) P2005-319488
Oct. 30, 2006 (JP) P2006-294494

(51) Int. Cl. H01L 29/739

(52) U.S. Cl. 257/194

(57) ABSTRACT

A field-effect transistor in the present invention has a source, a first gate, a second gate and a drain, which are formed in this order at positions away from each other on a semiconductor layer along the surface of the semiconductor layer and each of which has a metal electrode. The first gate has normally-off structure, while the second gate has normally-on structure. The first gate is of Schottky type, while the second gate is of MIS type.

### CROSS-REFERENCE TO RELATED APPLICATIONS

This Nonprovisional application claims priority under 35 U.S.C. §119(a) on Patent Applications No. 2005-319448 filed in Japan on Nov. 2, 2005 and No. 2006-294494 filed in Japan on Oct. 30, 2006, the entire contents of which are hereby incorporated by reference.

### BACKGROUND OF THE INVENTION

The present invention relates to a field-effect transistor and more specifically to a field-effect transistor with dual gate structure.

The present invention also relates to a switching circuit having such a field-effect transistor as a switching device.

As one of the field-effect transistors, a HFET (Heterostructure Field Effect Transistor) as shown in FIG. 9 is known (see, e.g., Hikita et al. “350V/150A AlGaN/GaN power HFET on Si substrate with source-via grounding structure”, the Journal of the Institute of Electronics, Information and Communication Engineers ED2004-212 to 226, pp. 1-5, (2005)). The HFET is composed of a buffer layer 1909 made of AlN, a layer 1902 made of undoped GaN, and a layer 1903 made of AlGaN, which are formed in this order on a silicon substrate 1901, and then, a Ti—Al source ohmic electrode 1905, a Pd—Si gate Schottky electrode 1906 and a Ti—Al drain ohmic electrode 1908 are formed thereon. A two-dimensional electron gas 1904 is generated in a boundary region between the GaN layer 1902 and the AlGaN layer 1903. The HFET is a “normally-on” type power switching device. It is to be noted that the normally-on type refers to the structure in which a carrier (two-dimensional electron gas in this example) can move across a channel region immediately below a zero-biased gate (metal electrode). During operation, the source electrode 1905 is grounded, while the drain electrode 1908 is connected to an unshown load circuit. Then, a gate driving signal is inputted into the gate electrode 1906, and an output is provided from the drain electrode 1908 to the load circuit.

FIG. 10 shows the cross sectional structure of a HFET having dual gate structure as a modified example of FIG. 9 (see. E.g., Chen et al. “Dual-Gate AlGaN/GaN Modulation-Doped Field-Effect Transistors with Cut-Off Frequencies f_{T}>60 GHz”, IEEE Electron Device Letters, Vol. 21, No. 12, pp. 549-551, 2000). The HFET is composed of a layer 2002 made of an undoped GaN with a thickness of approx. 3 μm, and a layer 2003 made of Al_{0.3}Ga_{0.7}N with a thickness of approx. 20 nm, which are formed in this order on a sapphire substrate 2001, and then, a Ti/Al/Ni/Au source ohmic electrode 2005, an Ni/Au first gate Schottky electrode 2006, an Ni/Au second gate Schottky electrode 200, and a Ti/Al/Ni/Au drain ohmic electrode 2008 are formed thereon. A two-dimensional electron gas 2004 is generated in a boundary region between the GaN layer 2002 and the AlGaN layer 2003. Both the gate electrodes 2006 and 2007 of the HFET, which are simultaneously formed on the layer 2003, have almost the same pinch-off voltage and have a normally-on structure. The first gate electrode 2006 and the second gate electrode 2007 are electrically independent from each other, while the second gate electrode 2007 and the source electrode 2005 are coupled via an unshown capacitor. Consequently, the HFET is cascode-connected not in a DC (Direct Current) region but only in a high-frequency region. During operation, the source electrode 2005 is grounded, while the drain electrode 2008 is connected to an unshown load circuit. Then, a DC bias is applied to the second gate electrode 2007, and a signal produced by superposing an RF input signal on a DC bias is applied to the first gate electrode 2006, so that an output is provided from the drain electrode 2008 to the load circuit. The HFET is a high-frequency amplifying device superior in high frequency characteristic to the HFET in FIG. 9.

FIG. 11 shows a “H-bridge” switching circuit composed of four HFETs shown in FIG. 9 (each designated by reference numerals 2101A, 2101B, 2101C and 2101D). The switching circuit includes a driver circuit 2100 for executing on-off control of four HFETs 2101A, 2101B, 2101C, 2101D at a specified timing, and freewheel diodes 2102A, 2102B, 2102C, 2102D respectively connected in antiparallel to the HFETs 2101A, 2101B, 2101C, 2101D. The freewheel diodes 2102A, 2102B, 2102C, 2102D are provided for bypassing a drain current of the reverse direction (charges swept out of the transistor) when the drain voltage is switched to a negative value with a large absolute value (generated in the case of inductance load) with the corresponding HFETs 2101A, 2101B, 2101C, 2101D being in ON state. Reference numeral 2103 denotes the inductance load. It is to be noted that simply omitting the freewheel diodes may apply a forward bias to the HFET gate and cause destruction of the HFET.

However, the conventional HFETs as shown in FIG. 9 and FIG. 10 have the following problems.

i) Large Transition Current in the Gate Electrode

During normal power switching operation, a source-drain voltage of the HFET periodically oscillates from low voltage to high voltage. Since most part of the source-drain voltage is applied to between the gate and the drain (voltage drop), a large amount of charges are stored in or discharged from the gate electrode due to the switching. This transitional flow of charges, i.e., transition current, should be supplied from a driver circuit (e.g., the driver circuit 2100 as shown in FIG. 11). In the case of conducting high-speed switching operation, the transition current becomes extremely large, which results in increase in power consumption of the driver circuit for driving the HFET. If the driver circuit cannot supply sufficient current, then the power consumption of the HFET also increases.

ii) Large Leakage Current from the Schottky Gate

Under the condition of high source-drain voltage, a leakage current between a metal electrode constituting the Schottky gate and a semiconductor layer immediately below thereof is increased, which causes a problem of low breakdown voltage in the Schottky gate.

It is to be noted that this problem becomes particularly noticeable when a recess groove is provided on the semiconductor layer and the metal electrode constituting the Schottky gate is provided in the recess grove so that the Schottky gate has normally-off structure. It is to be noted that “normally-off” structure refers to the structure which prohibits carriers from moving across a channel region immediately below the zero-biased gate (metal electrode).

iii) in the case of substituting a MIS (Metal-Insulator-Semiconductor)-type gate for the Schottky gate in order to decrease the leakage current, it becomes difficult to set a pinch-off voltage of the semiconductor layer immediately below the MIS-type gate, thereby making the MIS-type gate unstable. The MIS-type gate is composed of a metal electrode, an insulating layer immediately below thereof and a semiconductor layer. The unstability of the MIS-type gate is caused by the charges trapped in the insulating layer constituting the MIS-type gate.

Thus, the conventional HFETs as shown in FIG. 9 and FIG. 10 suffer various problems.

Further, since the switching circuit having the conventional HFET as shown in FIG. 11 needs the freewheel diodes 2101A, 2101B, 2101C, 2101D, the number of component parts increases, which causes a problem of increase in size and cost.

### SUMMARY OF THE INVENTION

An object of the present invention is to provide a field-effect transistor having small transition current and leakage current of the gate and having stable pinch-off voltage.

Another object of the present invention is to provide a switching circuit having such a field-effect transistor as a switching device.

In order to achieve the object, a field-effect transistor of the present invention comprises:

a source;

a first gate;

a second gate; and

a drain, which are formed in this order at positions away from each other on a semiconductor layer along a surface of the semiconductor layer and each of which has a metal electrode, wherein

the first gate has normally-off structure while the second gate has normally-on structure, and

the first gate is of Schottky type while the second gate is of MIS type.

The “normally-on” structure refers to the structure in which carriers can move across a channel region immediately below the zero-biased gate (metal electrode). The “normally-off” structure refers to the structure which prohibits carriers from moving across a channel region immediately below the zero-biased gate (metal electrode).

In the field-effect transistor in the present invention, during typical operation, high-frequency signals (including driving signals for switching and high-frequency input signals to be amplified) are applied to the first gate, while a DC bias is applied (or grounded) to the second gate. Since the source, the first gate, the second gate and the drain are arranged in this order, most part of a source-drain voltage is applied to between the second gate and the drain (voltage drop). Consequently, the magnitude of voltage applied to the first gate is limited, which makes a transition current of the first gate relatively small. As a result, the power consumption of the driver circuit for driving the field-effect transistor during switching operation is decreased. As for the second gate, the DC bias is applied (grounded) thereto, so that the driver circuit is free from a load.

In the field-effect transistor, even under the condition of high source-drain voltage, a maximum gate voltage applied to the first gate is equal to an absolute value of the pinch-off voltage of the second gate (e.g., approx. 5 V). Therefore, even with the first gate being structured to be the Schottky type, a leakage current between a metal electrode constituting the first gate and a semiconductor layer immediately below thereof is operationally suppressed compared to that in the conventional example (shown in FIG. 9). As a result, the breakdown voltage of the first gate does not pose a problem. Moreover, since the second gate has normally-on structure, its leakage current is lower than that of the normally-off gate.

Moreover, since the first gate has normally-off structure while the second gate has normally-on structure, the field-effect transistor as a whole has normally-off structure. Therefore, the field-effect transistor is suitable for constituting a switching device of a switching circuit.

In the field-effect transistor, the first gate has normally-off structure while the second gate has normally-on structure.

In the field-effect transistor, a leakage current between a metal electrode constituting the Schottky-type first gate and the semiconductor layer immediately below thereof is lower than that in the conventional example (shown in FIG. 9). Consequently, the breakdown voltage of the first gate does not pose a problem. Moreover, since the second gate is of MIS type, its leakage current is lower than that of the Schottky-type. Therefore, the field-effect transistor as a whole has a smaller leakage current of the gate.

Further, a pinch-off voltage of the field-effect transistor as a whole is determined by a pinch-off voltage of the first gate. Therefore, even when charges are trapped in an insulating layer constituting the MIS-type second gate and the pinch-off voltage of the second gate is thereby changed, the pinch-off voltage of the field-effect transistor as a whole suffers substantially no change. This makes it easy to set the pinch-off voltage and makes the pinch-off voltage stable.

In another aspect, a field-effect transistor of the present invention comprises:

a source;

a first gate;

a second gate; and

a drain, which are formed in this order at positions away from each other on a semiconductor layer along a surface of the semiconductor layer and each of which has a metal electrode, wherein

the first gate has normally-off structure while the second gate has normally-on structure, and

the second gate is electrically connected to the source through an interconnection.

In the field-effect transistor in the present invention, as in the field-effect transistor in the aforementioned aspect, the magnitude of voltage applied to the first gate is limited, which makes a transition current of the first gate relatively small. As a result, the power consumption of the driver circuit for driving the field-effect transistor during switching operation is decreased. As for the second gate, the DC bias is applied (grounded) thereto, so that the driver circuit is free from a load.

Moreover, in the field-effect transistor in the present invention, as in the field-effect transistor in the aforementioned aspect, a leakage current between a metal electrode constituting the first gate and a semiconductor layer immediately below thereof is operationally suppressed compared to that in the conventional example (shown in FIG. 9). As a result, the breakdown voltage of the first gate does not pose a problem. Moreover, since the second gate has normally-on structure, its leakage current is lower than that of the normally-off gate.

Moreover, since the first gate has normally-off structure while the second gate has normally-on structure, the field-effect transistor as a whole has normally-off structure. Therefore, the field-effect transistor is suitable for constituting a switching device of a switching circuit.

Moreover in the field-effect transistor, the second gate is electrically connected to the source through an interconnection, so that electric resistance between the second gate and the source is low. This enhances high-frequency characteristics.

In the field-effect transistor of one embodiment, the second gate is connected to the source through an air bridge interconnection.

The “air bridge interconnection” herein refers to an interconnection in which a central portion is hung in the air and only both end portions are supported.

In the field-effect transistor in this embodiment, the air bridge interconnection decreases the electric resistance between the second gate and the source to a negligible level. Along with this, an electrostatic capacitance regarding the second gate (such as an electrostatic capacitance between the first gate and the second gate) becomes lower than that in the case of other interconnections by wires and the like. This enhances high-frequency characteristics. This structure is equivalent to a cascode circuit.

When the HFET shifts from OFF state to ON state, a drain voltage becomes negative during the switching operation. In the HFET, when the drain voltage becomes a large negative value, a forward bias is applied to the second gate, and thereby charges flow from the drain contact, through the metal electrode constituting the second gate and to the source through the air bridge interconnection. Consequently, the magnitude of the forward bias voltage applied to the first gate is limited, which keeps a current flowing through the first gate small. This brings about an advantage in which freewheel diodes can be removed in the case of using the HFET as a switching device (details will be described later).

In the field-effect transistor of one embodiment,

a polyimide insulating film covering the first gate is formed between the source and the second gate, and

the second gate is connected to the source through an interconnection supported by the polyimide insulating film.

In the field-effect transistor in this embodiment, the interconnection decreases the electric resistance between the second gate and the source to a negligible level. Along with this, an electrostatic capacitance regarding the second gate (such as an electrostatic capacitance between the first gate and the second gate) becomes lower than that in the case of other interconnections by wires and the like. This enhances high-frequency characteristics. This structure is equivalent to a cascode circuit. Moreover, since the interconnection is supported by the polyimide insulating film, the structure is stabilized.

When the HFET shifts from OFF state to ON state a drain voltage becomes negative during the switching operation. In the HFET, when the drain voltage becomes a large negative value, a forward bias is applied to the second gate, and thereby charges flow from the drain contact, through the metal electrode constituting the second gate and to the source through the interconnection. Consequently, the magnitude of the forward bias voltage applied to the first gate is limited, which keeps a current flowing through the first gate small. This brings about an advantage in which freewheel diodes can be removed in the case of using the HFET as a switching device (details will be described later).

In the field-effect transistor of one embodiment,

each of the source, the first gate, the second gate and the drain has a pattern elongated in one direction on the semiconductor layer, and

the air bridge interconnection or the interconnection is elongated in a direction perpendicular to the one direction and is provided in a plurality of units in a periodic manner with respect to the one direction.

Since each of the source, the first gate, the second gate and the drain in the field-effect transistor in this embodiment has a pattern elongated in one direction on the semiconductor layer, a large current can be switched or amplified. Moreover, Since the air bridge interconnection or the interconnection is elongated in a direction perpendicular to the one direction and is provided in a plurality of units in a periodic manner with respect to the one direction, an electrostatic capacitance regarding the second gate (such as an electrostatic capacitance between the first gate and the second gate) does not increase too much.

In the field-effect transistor in one embodiment, between the second gate and the drain on the surface of the semiconductor layer, a dielectric film is provided so as to be at least in contact with the second gate.

As described above, in the field-effect transistor, most part of a source-drain voltage is applied to between the second gate and the drain (voltage drop). Consequently, dielectric breakdown particularly in the vicinity of the second gate becomes a problem. In the field-effect transistor in this embodiment, the dielectric film is provided between the second gate and the drain on the surface of the semiconductor layer so as to be at least in contact with the second gate, and this decreases a maximum electric field between the second gate and the drain and thereby prevents the dielectric breakdown particularly in the vicinity of the second gate. Since the concentration of the electric field does not occur even with a high carrier concentration of two-dimensional electron gas, dielectric breakdown withstand voltage can be set high even with low channel resistance.

A dielectric constant of the dielectric film should preferably be higher than the dielectric constant of the semiconductor layer. In this case, a maximum electric field between the second gate and the drain can effectively be decreased.

A switching circuit of the present invention comprises the above field-effect transistor as a switching device.

In the switching circuit of the present invention, the first gate of the field-effect transistor as a switching device has normally-off structure while the second gate has normally-on structure, and therefore the transistor as a whole has normally-off structure. As a result, an output current against a load can easily be blocked in the normal state.

During typical high-frequency switching operation, high-frequency signals for switching are applied to the first gate, while a DC bias is applied (or grounded) to the second gate. Since the source, the first gate, the second gate and the drain are arranged in this order, most part of a source-drain voltage is applied to between the second gate and the drain (voltage drop). Consequently, the magnitude of voltage applied to the first gate is limited, which makes a transition current of the first gate relatively small. As a result, the power consumption of the driver circuit for driving the field-effect transistor during switching operation is decreased. As for the second gate, the DC bias is applied (grounded) thereto, so that the driver circuit is free from a load.

In another aspect, a field-effect transistor of the present invention comprises:

a source;

a first gate;

a second gate; and

a drain, which are formed in this order at positions away from each other on a semiconductor layer along a surface of the semiconductor layer and each of which has a metal electrode, wherein

the first gate is of Schottky type, while the second gate is of MIS type.

In the field-effect transistor in this embodiment, a leakage current between a metal electrode constituting the Schottky-type first gate and the semiconductor layer immediately below thereof is lower than that in the conventional example (shown in FIG. 9). Consequently, the breakdown voltage of the first gate does not pose a problem. Moreover, since the second gate is of MIS type, its leakage current is lower than that of the Schottky-type. Therefore, the field-effect transistor as a whole has a smaller leakage current of the gate.

Moreover, a pinch-off voltage of the field-effect transistor as a whole is determined by a pinch-off voltage of the first gate. Therefore, even when charges are trapped in an insulating layer constituting the MIS-type second gate and the pinch-off voltage of the second gate is thereby changed, the pinch-off voltage of the field-effect transistor as a whole suffers substantially no change. This makes it easy to set the pinch-off voltage and makes the pinch-off voltage stable.

In another aspect, a field-effect transistor of the present invention comprises:

a source;

a first gate;

a second gate; and

a drain, which are formed in this order at positions away from each other on a semiconductor layer along a surface of the semiconductor layer and each of which has a metal electrode, wherein

the first gate has normally-off structure while the second gate has normally-on structure,

the first gate is of Schottky type, while the second gate is of MIS type, and

the second gate is electrically connected to the source through an interconnection.

The field-effect transistor in the present invention has the functions and the effects stated with respect to the field-effect transistors in each aspect described above.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a view showing the cross sectional structure of a HFET in one embodiment of the present invention;

FIG. 2 is a view showing the cross sectional structure of a HFET in another embodiment of the present invention;

FIG. 3 is a view showing the cross sectional structure of a HFET in still another embodiment of the present invention;

FIG. 4A is a view showing an example in which a dielectric film is provided so as to be in contact with the second gate of the HFET in FIG. 3;

FIG. 4B is a view showing an example in which a dielectric film is provided so as to be in contact with the second gate of the HFET in FIG. 3;

FIG. 4C is a view showing an example in which a dielectric film is provided so as to be in contact with the second gate of the HFET in FIG. 3;

FIG. 4D is a view showing an example in which a dielectric film is provided so as to be in contact with the second gate of the HFET in FIG. 3;

FIG. 4E is a view showing an example in which a dielectric film is provided so as to be in contact with the second gate of the HFET in FIG. 3;

FIG. 5A is a view showing the cross sectional structure of a HFET in a more specified embodiment;

FIG. 5B is a view showing a plan layout of FIG. 5A as seen from the upper side;

FIG. 6A is a view showing the cross sectional structure of a HFET in still another embodiment;

FIG. 6B is a view showing a plan layout of FIG. 6A as seen from the upper side;

FIG. 7A is a view showing the cross sectional structure of a HFET in still another embodiment;

FIG. 7B is a view showing a plan layout of FIG. 7A as seen from the upper side;

FIG. 8 is a view showing the structure of a switching circuit having the HFET shown in FIGS. 5A and 5B;

FIG. 9 is a view showing the structure of a conventional GaN high-power HFET;

FIG. 10 is a view showing the structure of a conventional dual gate high-frequency GaN HFET; and

FIG. 11 is a view showing the structure of a conventional H-bridge switching circuit having four HFETs shown in FIG. 9.

### DETAILED DESCRIPTION OF THE INVENTION

Hereinbelow, the invention will be described in detail in conjunction with the embodiments with reference to the drawings.

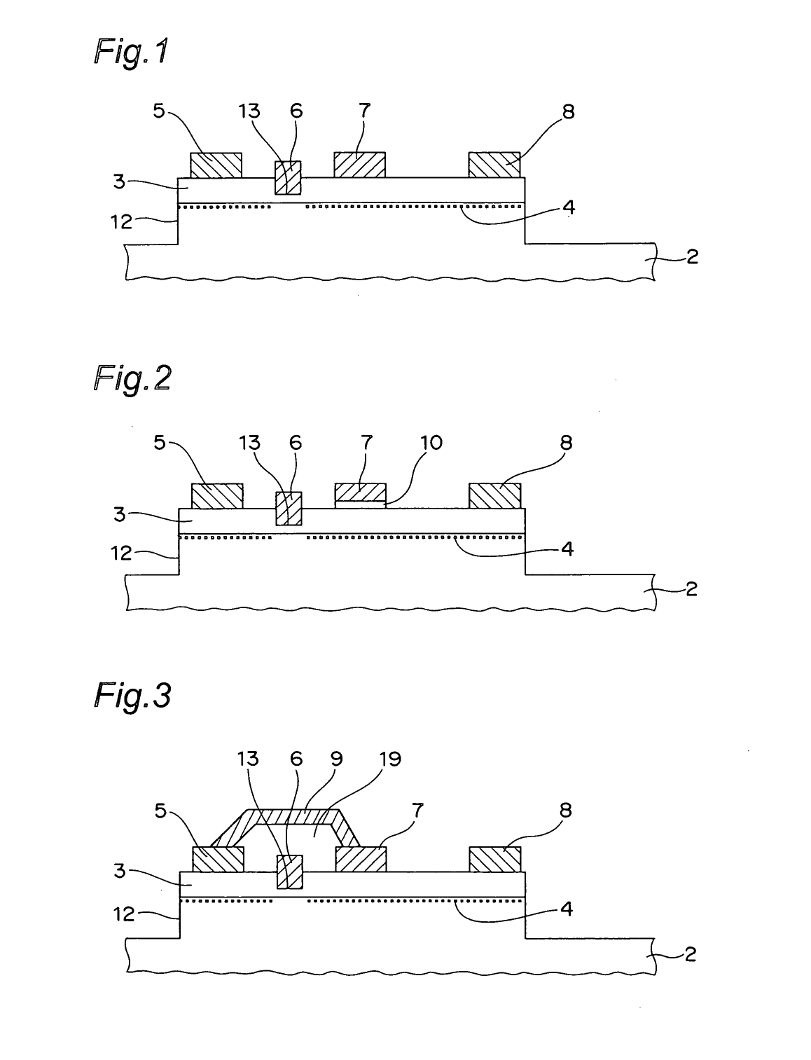

FIG. 1 shows the cross sectional structure of a HFET (Heterostructure Field Effect Transistor) in one embodiment.

The HFET has an AlGaN layer 3 on an undoped GaN layer 2. These semiconductor layers 2 and 3 are patterned to constitute a mesa 12. Along an interface between the GaN layer 2 and the AlGaN layer 3, a two-dimensional electron gas (2DEG) 4 is generated. On the AlGaN layer 3, metal electrodes are provided at positions away from each other along the surface of the layer 3 to form a source 5, a first gate 6, a second gate 7 and a drain 8 in this order. The metal electrodes constituting the source 5 and the drain 8 are in ohmic contact with the AlGaN layer 3 immediately below thereof. The metal electrodes constituting the first gate 6 and the second gate 7 form Schottky junction with the AlGaN layer 3 immediately below thereof.

The first gate 6, which is formed so as to fill a recess groove 13 formed through etching of the AlGaN layer 3, has normally-off structure. The second gate 7, which is formed on the surface of the AlGaN layer 3, has normally-on structure.

It is to be noted that “normally-on” and “normally-off” structures respectively refer to the structures in which electrons constituting the two-dimensional electron gas can and cannot move across a channel region immediately below the zero-biased gate (metal electrode).

In the HFET, during typical operation, high-frequency signals (including driving signals for switching and high-frequency input signals to be amplified) are applied to the first gate 6, while a DC bias is applied (or grounded) to the second gate 7. Since the source 5, the first gate 6, the second gate 7 and the drain 8 are arranged in this order, most part of a source-drain voltage is applied to between the second gate 7 and the drain 8 (voltage drop). This makes a transition current of the first gate 6 relatively small. As a result, the power consumption of the driver circuit for driving the HFET during switching operation is decreased. As for the second gate 7, the DC bias is applied (grounded) thereto, so that the driver circuit is free from a load.

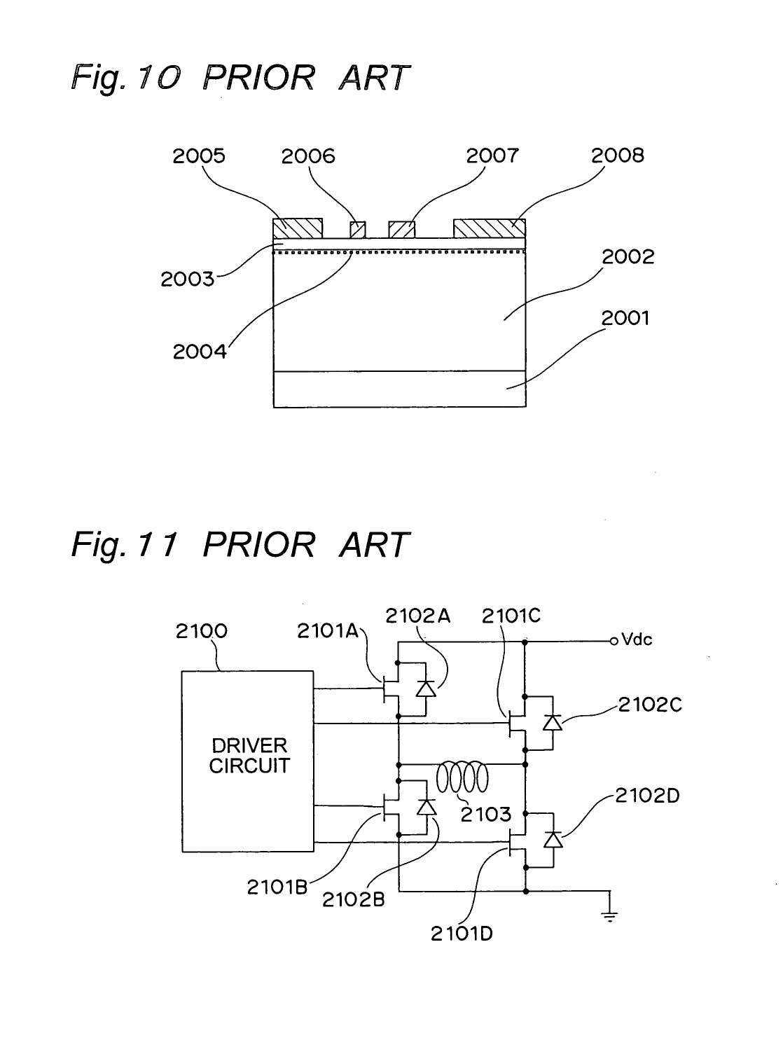

In the HFET, even under the condition of high source-drain voltage, a maximum gate voltage applied to the first gate 6 is equal to an absolute value of the pinch-off voltage of the second gate 7 (e.g., approx. 5 V). Therefore, the leakage current between a metal electrode constituting the Schottky-type first gate 6 and the AlGaN layer 3 immediately below thereof is operationally suppressed compared to that in the conventional example (shown in FIG. 9). As a result, the breakdown voltage of the first gate 6 does not pose a problem. Moreover, since the second gate 7 has normally-on structure, its leakage current is lower than that of the normally-off gate.

Moreover, since the first gate 6 has normally-off structure while the second gate 7 has normally-on structure, the HFET as a whole has normally-off structure. Therefore, the HFET is suitable for constituting a switching device of a switching circuit.

FIG. 2 shows the cross sectional structure of a HFET in another embodiment. It is to be noted that component members in FIG. 2 corresponding to the component members in FIG. 1 are designated by identical reference numerals and overlapping description thereof will be omitted (unless otherwise specified, the HFET in FIG. 2 has the structure similar to that in FIG. 1 and therefore achieves similar functions and effects. This applies in the following embodiments).

In the HFET, the first gate 6 is of Schottky type like the first gate 6 in FIG. 1, whereas the second gate 7 is of MIS (Metal-Insulator-Semiconductor) type. Reference numeral 10 in the drawing denotes an insulating layer made of HfO₂ constituting the MIS-type second gate 7. HfO₂ is desirable as it has high dielectric constant and high dielectric breakdown strength.

In the HFET, a leakage current between a metal electrode constituting the Schottky-type first gate 6 and the AlGaN layer 3 immediately below thereof is lower than that in the conventional example (shown in FIG. 9). Consequently, the breakdown voltage of the first gate 6 does not pose a problem. Moreover, since the second gate 7 is of MIS type, its leakage current is lower than that of the Schottky type. Therefore, the HFET as a whole has a smaller leakage current of the gate.

Moreover, a pinch-off voltage of the HFET as a whole is determined by a pinch-off voltage of the first gate 6. Therefore, even when charges are trapped in the insulating layer 10 constituting the MIS-type second gate 7 and the pinch-off voltage of the second gate 7 is thereby changed, the pinch-off voltage of the HFET as a whole suffers substantially no change. This makes it easy to set the pinch-off voltage and makes the pinch-off voltage stable.

FIG. 3 shows the cross sectional structure of a HFET in still another embodiment.

In the HFET, the second gate 7 is electrically connected to the source 5 through an air bridge interconnection 9.

In the HFET, the air bridge interconnection 9 decreases the electric resistance between the second gate 7 and the source 5 to a negligible level. Along with this, an electrostatic capacitance regarding the second gate 7 (such as an electrostatic capacitance between the first gate 6 and the second gate 7) becomes lower than that in the case of other interconnections by wires and the like. This enhances high-frequency characteristics. This structure is equivalent to a cascode circuit.

In the case where each of the source 5, the first gate 6, the second gate 7 and the drain 8 has a pattern elongated in one direction on the semiconductor layer, the interconnection should preferably be provided in a plurality of units in a periodic manner with respect to the one direction. This enhances high-frequency characteristics.

When the HFET shifts from OFF state to ON state a drain voltage becomes negative during the switching operation. In the HFET, when the drain voltage becomes a large negative value, a forward bias is applied to the second gate 7, and thereby charges flow from the drain contact, through the metal electrode constituting the second gate 7 and to the source 5 through the interconnection 9. Consequently, the magnitude of the forward bias voltage applied to the first gate 6 is limited, which keeps a current flowing through the first gate 6 small. This brings about an advantage in which freewheel diodes can be removed in the case of using the HFET as a switching device (details will be described later).

It is to be noted that a polyimide insulating film (unshown) may be provided in a space 19 immediately below the air bridge interconnection 9 between the source 5 and the second gate 7 so as to cover the first gate 6 and that the interconnection 9 may be supported by the polyimide insulating film. This stabilizes the structure.

In the HFETs shown in FIG. 1 to FIG. 3, most part of a source-drain voltage is applied to between the second gate 7 and the drain 8 (voltage drop). This may cause a problem of dielectric breakdown particularly in the vicinity of the second gate 8.

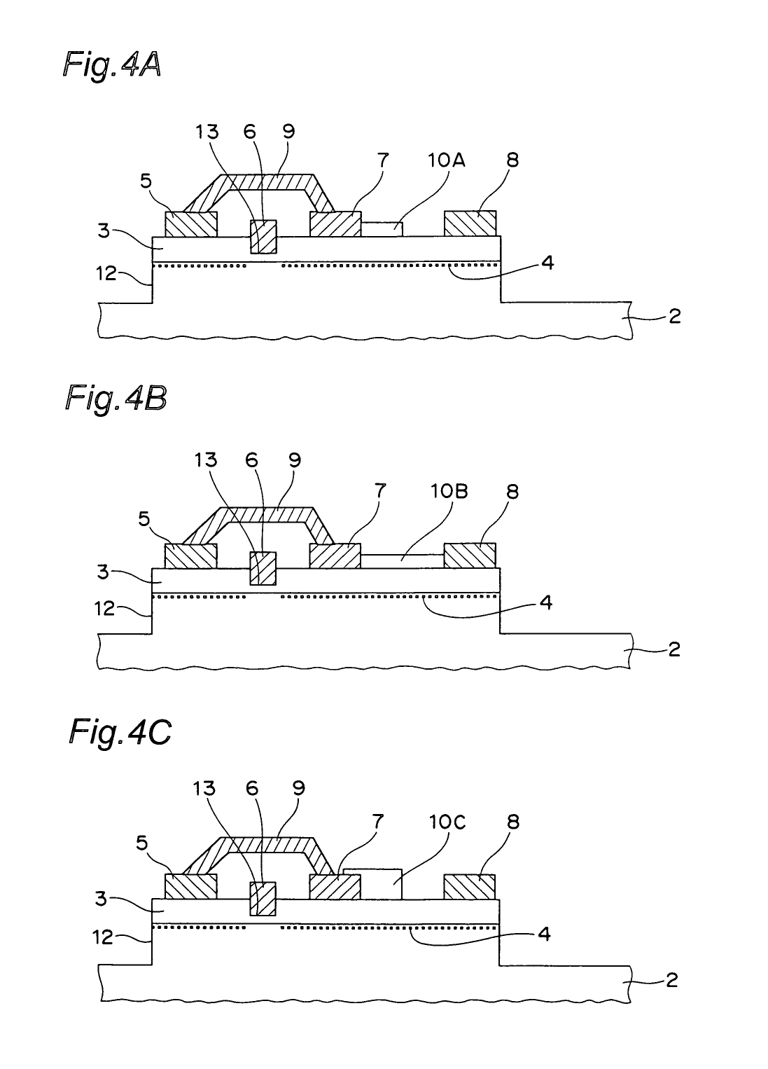

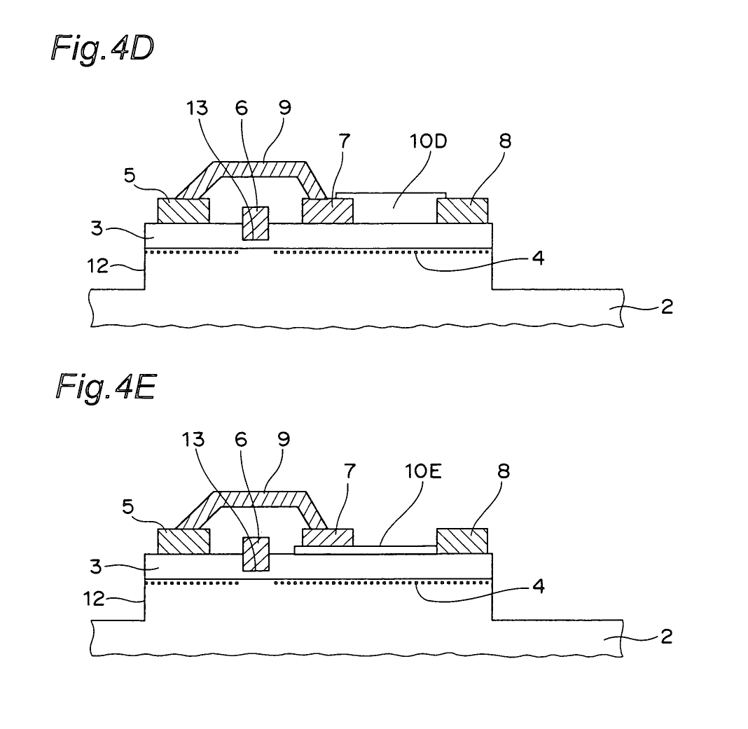

FIG. 4A to FIG. 4E show examples in which dielectric films 10A to 10E are placed on the HFET in FIG. 3 so as to be in contact with the second gate 7.

In the HFET in FIG. 4A, a dielectric film 10A is placed on a region corresponding to the half of the surface of the AlGaN layer 3 between the second gate 7 and the drain 8, the region close to the second gate 7.

In the HFET in FIG. 4B, a dielectric film 10B is placed on the entire surface of the AlGaN layer 3 between the second gate 7 and the drain 8.

In the HFET in FIG. 4C, a dielectric film 10C is placed on a region generally corresponding to the half of the surface of the AlGaN layer 3 between the second gate 7 and the drain 8, the region close to the second gate 7, so as to be overlapped with the second gate 7.

In the HFET in FIG. 4D, a dielectric film 10D is placed on the entire surface of the AlGaN layer 3 between the second gate 7 and the drain 8 so as to be overlapped with the second gate 7 and the drain 8.

In the HFET in FIG. 4E, a dielectric film 10E is placed on the entire surface of the AlGaN layer 3 between the second gate 7 and the drain 8 so as to extend immediately below the metal electrode of the second gate 7. As a result, the second gate 7 becomes the MIS type.

In the examples in FIG. 4A to FIG. 4E, the dielectric films 10A to 10E decrease a maximum electric field between the second gate 7 and the drain 8 and prevents dielectric breakdown particularly in the vicinity of the second gate 7. Moreover, since the concentration of the electric field does not occur even with a high carrier concentration of the two-dimensional electron gas 4, dielectric breakdown withstand voltage can be set high even with low channel resistance.

A dielectric constant of the dielectric films 10A to 10E should preferably be higher than the dielectric constant of the GaN layer 2 and the AlGaN layer 3. The thickness of the dielectric films 10A to 10E should preferably be larger than 2000 Å. In this case, the maximum electric field between the second gate 7 and the drain 8 can effectively be decreased.

Specific materials of the dielectric films 10A to 10E include TiO₂, HfO₂, TaOx and NbOx in terms of the dielectric constant and the dielectric breakdown strength.

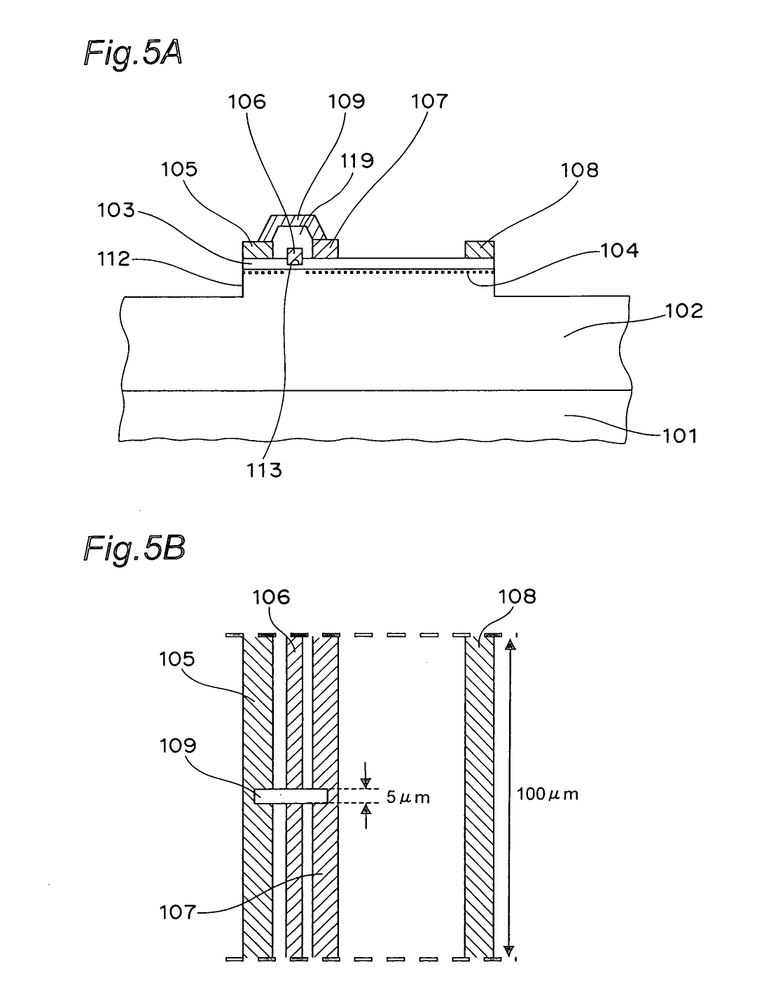

FIG. 5A shows the cross sectional structure of a HFET in a more specified example, and FIG. 5B shows a plan layout of FIG. 5A as seen from the upper side.

As shown in FIG. 5A, the HFET has an undoped GaN layer 102 with a thickness of 3 μm and an Al_{0.3}Ga_{0.7}N layer 103 with a thickness of 25 nm on a sapphire substrate 101. These semiconductor layers 102 and 103 are patterned to constitute a mesa 112. Along an interface between the GaN layer 102 and the Al_{0.3}Ga_{0.7}N layer 103, a two-dimensional electron gas (2DEG) 104 with a carrier concentration of nₛ=8×10¹² cm⁻² is generated. On the Al_{0.3}Ga_{0.7}N layer 103, metal electrodes are provided at positions away from each other along the surface of the layer 103 to form a source 105, a first gate 106, a second gate 107 and a drain 108 in this order. The metal electrodes constituting the source 105 and the drain 108 are made of a laminated layer of Ti/Al/Au and are in ohmic contact with the Al_{0.3}Ga_{0.7}N layer 103 immediately below thereof. The metal electrodes constituting the first gate 106 and the second gate 107 are made of a laminated layer of WN/Au and form Schottky junction with the Al_{0.3}Ga_{0.7}N layer 103 immediately below thereof. The first gate 106 has a gate length of 0.5 μm and the second gate 107 has a gate length of 1.0 μm. A distance between the second gate 107 and the drain 108 is 5 μm.

The first gate 106, which is formed so as to fill a recess groove 113 formed through etching of the Al_{0.3}Ga_{0.7}N layer 103, has normally-off structure. In concrete, the thickness of the Al_{0.3}Ga_{0.7}N layer 103 left immediately below the recess groove 113 is only 80 Å, as a result of which the pinch-off voltage of the first gate 106 is +0.3 V. The second gate 107, which is formed on the surface of the Al_{0.3}Ga_{0.7}N layer 103, has normally-on structure. In concrete, the pinch-off voltage of the second gate 107 is −5 V. The first gate 106 has relatively low electrostatic capacitance and low breakdown voltage, whereas the second gate 107 has relatively low transition current and high breakdown voltage.

In the HFET, during typical operation, high-frequency signals (including driving signals for switching and high-frequency input signals to be amplified) are applied to the first gate 106, while a DC bias is applied (or grounded) to the second gate 107. Since the source 105, the first gate 106, the second gate 107 and the drain 108 are arranged in this order, most part of a source-drain voltage is applied to between the second gate 107 and the drain 108 (voltage drop). This makes a transition current of the first gate 106 relatively small. As a result, the power consumption of the driver circuit for driving the HFET during switching operation is decreased. As for the second gate 107, the DC bias is applied (grounded) thereto, so that the driver circuit is free from a load.

In the HFET, even under the condition of high source-drain voltage, a maximum gate voltage applied to the first gate 106 is equal to an absolute value of the pinch-off voltage of the second gate 107 (e.g., approx. 5 V). Therefore, the leakage current between a metal electrode constituting the Schottky-type first gate 106 and the Al_{0.3}Ga_{0.7}N layer 103 immediately below thereof is operationally suppressed compared to that in the conventional example (shown in FIG. 9). As a result, the breakdown voltage of the first gate 106 does not pose a problem. Moreover, since the second gate 107 has normally-on structure, its leakage current is lower than that of the normally-off gate.

In the HFET, the second gate 107 is electrically connected to the source 105 through an air bridge interconnection 109 made of a laminated layer of Ti/Pt/Au. The air bridge interconnection 109 decreases the electric resistance between the second gate 107 and the source 105 to a negligible level. Along with this, an electrostatic capacitance regarding the second gate 107 (such as an electrostatic capacitance between the first gate 106 and the second gate 107) becomes lower than that in the case of other interconnections by wires and the like. This enhances high-frequency characteristics. This structure is equivalent to a cascode circuit.

As shown in FIG. 5B, each of the source 105, the first gate 106, the second gate 107 and the drain 108 has a pattern elongated in one direction (vertical direction in FIG. 5B) so as to achieve switching or amplification of a large current. The air bridge interconnection 109 has a pattern with a width of 5 μm, which is elongated in a direction perpendicular to the one direction (horizontal direction in FIG. 5B). The air bridge interconnection 109 is provided in a plurality of units in a periodic manner with respect to the vertical direction in FIG. 5B, more specifically, with 100 μm pitch as shown in FIG. 5B. In a typical example, the air bridge interconnection in FIG. 5B has a vertical pattern size (gate width) of 60 mm, and the HFET includes 600 constitutional units of the air bridge interconnection in FIG. 5B. Thus, since the air bridge interconnection 109 has the elongated pattern provided in the periodic manner, the electrostatic capacitance regarding the second gate 107 (such as the electrostatic capacitance between the first gate 106 and the second gate 107) does not increase too much.

When the HFET shifts from OFF state to ON state a drain voltage becomes negative during the switching operation. In the HFET, when the drain voltage becomes a large negative value, a forward bias is applied to the second gate 107, and thereby charges flow from the drain contact, through the metal electrode constituting the second gate 107 and to the source 105 through the interconnection 109. Consequently, the magnitude of the forward bias voltage applied to the first gate 106 is limited, which keeps the current flowing through the first gate 106 small. This brings about an advantage in which freewheel diodes can be removed in the case of using the HFET as a switching device (details will be described later).

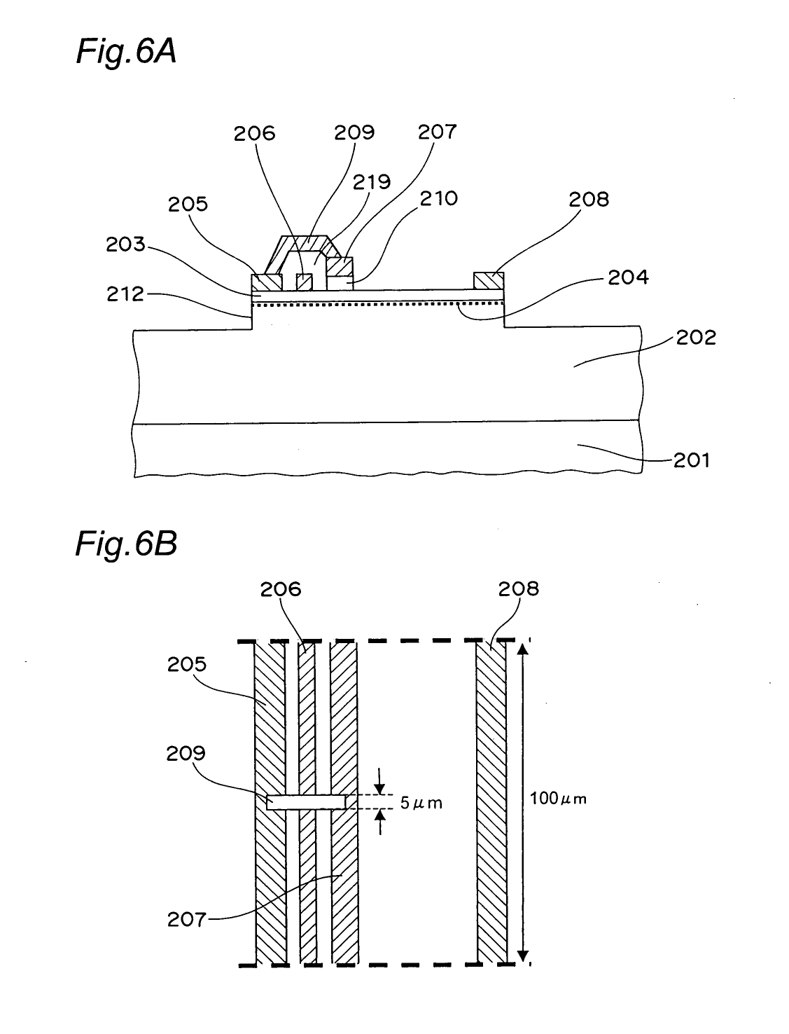

FIG. 6A shows the cross sectional structure of a HFET in still another embodiment, and FIG. 6B shows a plan layout of FIG. 6A as seen from the upper side. It is to be noted that component members in FIGS. 6A and 6B corresponding to the component members in FIGS. 5A and 5B are designated by reference numerals with 100 added thereto and overlapping description thereof will be omitted (unless otherwise specified, the HFET in FIGS. 6A and 6B has the structure similar to that in FIGS. 5A and 5B and therefore achieves similar functions and effects).

As with the HFET in FIGS. 5A and 5B, metal electrodes constituting a source 205 and a drain 208 are made of a laminated layer of Ti/Al/Au and are in ohmic contact with the Al_{0.3}Ga_{0.7}N layer 203 immediately below thereof. Metal electrodes constituting a first gate 206 and a second gate 207 are made of a laminated layer of WN/Au.

In the HFET, the metal electrode constituting the first gate 206 is provided on the surface of an Al_{0.3}Ga_{0.7}N layer 203 to form Schottky junction. The first gate 206 is of Schottky type as with the first gate in FIGS. 5A and 5B, though its pinch-off voltage is −5 V. The second gate 207 is of MIS type and has an insulating layer 210 made of HfO₂. HfO₂ is desirable as it has high dielectric constant and high dielectric breakdown strength.

The first gate 206 has a gate length of 0.5 μm and the second gate 207 has a gate length of 1.0 μm. A distance between the second gate 207 and the drain 208 is 3 μm.

In the HFET, a leakage current between a metal electrode constituting the Schottky-type first gate 206 and the AlGaN layer 203 immediately below thereof is lower than that in the conventional example (shown in FIG. 9). As a result, the breakdown voltage of the first gate 206 does not pose a problem. Moreover, since the second gate 207 is of MIS type, its leakage current is lower than that of Schottky type. Therefore, the HFET as a whole has a smaller leakage current of the gate.

Moreover, a pinch-off voltage of the HFET as a whole is determined by a pinch-off voltage of the first gate 206. Therefore, even when charges are trapped in the insulating layer 210 constituting the MIS-type second gate 207 and the pinch-off voltage of the second gate 207 is thereby changed, the pinch-off voltage of the HFET as a whole suffers substantially no change. This makes it easy to set the pinch-off voltage and makes the pinch-off voltage stable.

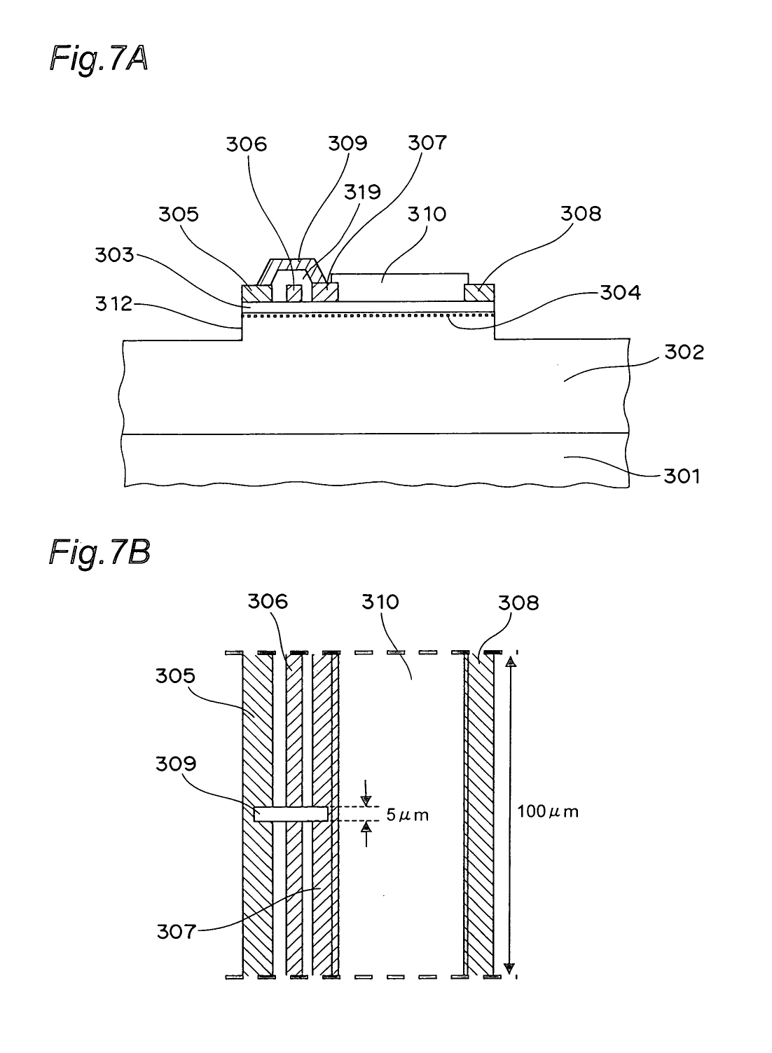

FIG. 7A shows the cross sectional structure of a HFET in yet another embodiment, and FIG. 7B shows a plan layout of FIG. 7A as seen from the upper side. It is to be noted that component members in FIGS. 7A and 7B corresponding to the component members in FIGS. 5A and 5B are designated by reference numerals with 200 added thereto and overlapping description thereof will be omitted (unless otherwise specified, the HFET in FIGS. 7A and 7B has the structure similar to that in FIGS. 5A and 5B and therefore achieves similar functions and effects).

As with the HFET in FIGS. 5A and 5B, metal electrodes constituting a source 305 and a drain 308 are made of a laminated layer of Ti/Al/Au and are in ohmic contact with the Al_{0.3}Ga_{0.7}N layer 303 immediately below thereof. Metal electrodes constituting a first gate 306 and a second gate 307 are made of a laminated layer of WN/Au and form Schottky junction with the Al_{0.3}Ga_{0.7}N layer 303 immediately below thereof.

In the HFET, both the first gate 306 and the second gate 307 are provided on the surface of the Al_{0.3}Ga_{0.7}N layer 303 immediately below thereof and has normally-on structure. The pinch-off voltages of the first gate 306 and the second gate 307 are both −5 V.

Moreover, in the HFET, an dielectric film 310 is provided on the entire surface of the Al_{0.3}Ga_{0.7}N layer 303 between the second gate 307 and the drain 308 so as to be overlapped with both the second gate 307 and the drain 308. The dielectric film 310 is made of TiO₂ with a thickness of 4000 Å. TiO₂ is desirable as it has high dielectric constant and high dielectric breakdown strength. The dielectric film 310 decreases a maximum electric field between the second gate 307 and the drain 308 and prevents dielectric breakdown particularly in the vicinity of the second gate 307. Moreover, since the concentration of the electric field does not occur even with a high carrier concentration of a two-dimensional electron gas 304, dielectric breakdown withstand voltage can be set high even with low channel resistance.

However, since an electrostatic capacitance relating to the second gate 307 is increased by the dielectric film 310, a transition current passing the second gate 307 during switching operation is increased proportionally. Still, a greater part of the source-drain voltage is supported between the second gate 307 and the drain 308 (voltage drop). Consequently, the magnitude of the voltage applied to the first gate 306 is limited, which makes the transition current in the first gate 306 relatively small. As a result, the power consumption of the driver circuit for driving the HFET during switching operation is decreased.

Next, a charge amount per 1 mm gate width in the first gate 306 and the second gate 307 at the moment that the HFET is switched is calculated.

When a source-drain voltage (OFF state voltage) is 500 V, a charge amount ΔQ2 per 1 mm gate width in the second gate 307 is obtained in the following equation:
ΔQ2=q·ns·(Lg2+Lg2d)+500×Cgeo=152 pJ/mm (1)
herein q represents an electron charge, ns represents a concentration of non-depleted two-dimensional electron gas, Lg2 represents a gate length of the second gate 307, Lg2d represents a distance between the second gate 307 and the drain 308, and Cgeo represents a geometric capacitance (approx. 150 fF/mm) between the second gate 307 and the drain 308. The capacitance Cgeo is increased by the presence of the dielectric film (TiO₂) 310.

A charge amount ΔQ1 per 1 mm gate width in the first gate 306 is obtained in the following equation:
ΔQ1=q·ns·Lg=6.4 pJ/mm (2)

The results of the calculations indicate that the charge amount ΔQ1 per 1 mm gate width in the first gate 306 is sufficiently smaller than the charge amount ΔQ2 per 1 mm gate width in the second gate 307. Therefore, the power consumption of the driver circuit for driving the HFET is decreased as described above.

In the case of the conventional HFET (shown in FIG. 9) having a single gate, a charge amount as large as the ΔQ2 flows through the driver circuit, resulting in large power consumption. In the case of devices with high switching speed such as GaN-type HFETs, a current at the moment of switching becomes large. The current, if limited by the driver circuit, lowers the switching speed and increases the power consumption of HFETs. Therefore, the present invention is effective for the GaN-type HFETs. Moreover, since the dielectric film 310 increases the electrostatic capacitance relating to the second gate 307, the transition current passing the second gate 307 during switching operation is increased proportionally. Therefore, the present invention is particularly effective for HFETs having such a dielectric film 310.

It is to be noted that in the case where both the first gate 306 and the second gate 307 have normally-on structure as with the HFET shown in FIGS. 7A and 7B, the second gate 307 may be of MIS type.

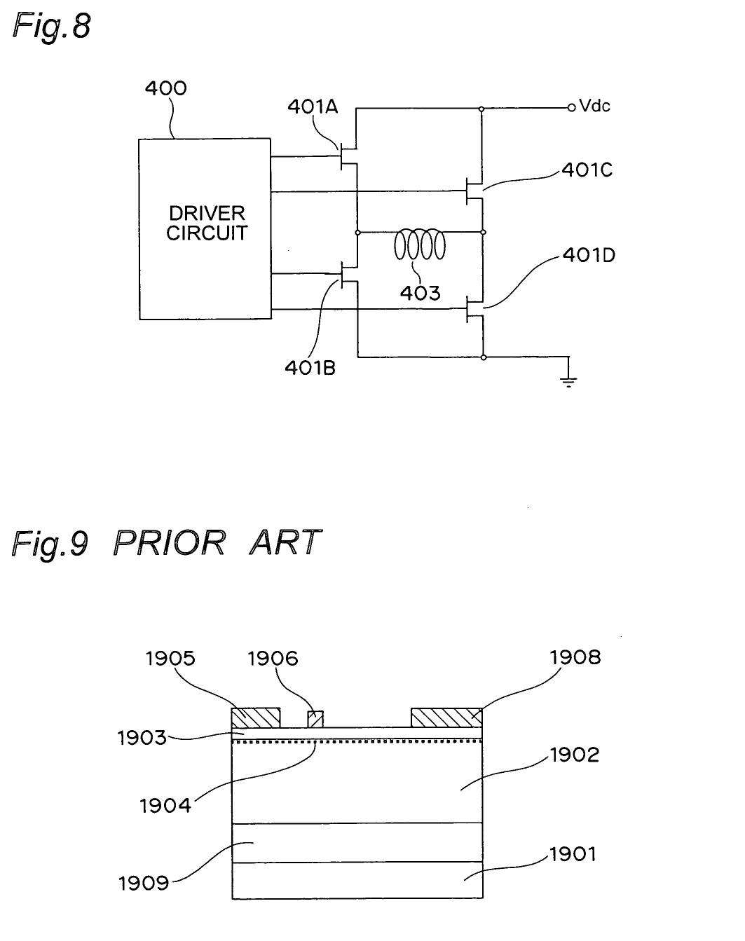

FIG. 8 shows a “H-bridge” switching circuit composed of, for example, four HFETs (each designated by reference numerals 401A, 401B, 401C and 401D) shown in FIGS. 5A and 5B. The switching circuit includes a driver circuit 400 for executing on-off control of four HFETs 401A, 401B, 401C, 401D at a specified timing. Reference numeral 403 denotes an inductance load. When the drain voltage is switched to a negative value with a large absolute value (generated in the case of inductance load), the drain current of reverse direction is bypassed from the metal electrode constituting the second gate 107 to the source 105 through the air bridge interconnection 109 as described before. Consequently, the magnitude of the forward bias voltage applied to the first gate 106 is limited, which makes a current in the first gate 106 relatively small. Therefore, the freewheel diodes which are required in the conventional switching circuit (see FIG. 11) are no longer necessary.

Although description has been given of the GaN-type HFET in the present embodiment, the present invention is not limited thereto. The present invention is widely applicable to field-effect transistors having dual gate structure.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A field-effect transistor, comprising:
a source;
a first gate;
a second gate; and
a drain, which are formed in this order at positions away from each other on a semiconductor layer along a surface of the semiconductor layer and each of which has a metal electrode, wherein
the first gate has normally-off structure while the second gate has normally-on structure, and
the first gate is of Schottky type while the second gate is of MIS type.

2. A field-effect transistor, comprising:
a source;
a first gate;
a second gate; and
a drain, which are formed in this order at positions away from each other on a semiconductor layer along a surface of the semiconductor layer and each of which has a metal electrode, wherein
the first gate has normally-off structure while the second gate has normally-on structure, and
the second gate is electrically connected to the source through an interconnection.

3. The field-effect transistor according to claim 2, wherein
the second gate is connected to the source through an air bridge interconnection.

4. The field-effect transistor according to claim 2, wherein
a polyimide insulating film covering the first gate is formed between the source and the second gate, and
the second gate is connected to the source through an interconnection supported by the polyimide insulating film.

5. The field-effect transistor according to claim 4, wherein
each of the source, the first gate, the second gate and the drain has a pattern elongated in one direction on the semiconductor layer, and
the air bridge interconnection or the interconnection is elongated in a direction perpendicular to the one direction and is provided in a plurality of units in a periodic manner with respect to the one direction.

6. The field-effect transistor according to claim 2, wherein
on a surface of the semiconductor layer between the second gate and the drain, a dielectric film having a dielectric constant higher than the dielectric constant of a semiconductor active layer is formed so as to be at least in contact with the second gate.

7. A switching circuit comprising the field-effect transistor according to claim 2 as a switching device.

8. A field-effect transistor, comprising:
a source;
a first gate;
a second gate; and
a drain, which are formed in this order at positions away from each other on a semiconductor layer along a surface of the semiconductor layer and each of which has a metal electrode, wherein
the first gate is of Schottky type, while the second gate is of MIS type.

9. A field-effect transistor, comprising:
a source;
a first gate;
a second gate; and
a drain, which are formed in this order at positions away from each other on a semiconductor layer along a surface of the semiconductor layer and each of which has a metal electrode, wherein
the first gate has normally-off structure while the second gate has normally-on structure,
the first gate is of Schottky type, while the second gate is of MIS type, and
the second gate is electrically connected to the source through an interconnection.
